(19) United States
(12) Patent Application Publication
(10) Pub. No.: US 2025/0248239 A1
(43) Pub. Date: Jul. 31, 2025

(54) DISPLAY DEVICE AND ELECTRONIC DEVICE INCLUDING THE SAME

(71) Applicant: Samsung Display Co., Ltd., Yongin-si (KR)

(72) Inventors: SOOYOUN KIM, Yongin-si (KR); OHJUNE KWON, Yongin-si (KR); HYOJEONG KWON, Yongin-si (KR); WOO YONG SUNG, Yongin-si (KR); Hee Jun Yang, Yongin-si (KR); Soomin Oh, Yongin-si (KR); JEONGSEOK LEE, Yongin-si, Gyeonggi-do (KR); JINHO HYUN, Yongin-si (KR); Sangyeon Hwang, Yongin-si (KR)

(21) Appl. No.: 19/011,594

(22) Filed: Jan. 7, 2025

(30) Foreign Application Priority Data
Jan. 26, 2024 (KR) 10-2024-0012469

(51) Int. Cl. H10K 59/126; H10K 59/80

(52) U.S. Cl. CPC H10K 59/126; H10K 59/8794

(57) ABSTRACT

A display device includes: a substrate including a display area and a bending area positioned on one side of the display area, a lower surface of the substrate defining a plurality of openings; a shielding layer disposed along a profile of the lower surface of the substrate and continuously extending within the plurality of openings; and a first organic layer disposed under the shielding layer and flattening a lower surface of the shielding layer.

### CROSS-REFERENCE TO RELATED APPLICATION

This application claims priority under 35 USC § 119 to Korean Patent Application No. 10-2024-0012469, filed on Jan. 26, 2024, in the Korean Intellectual Property Office, the content of which is herein incorporated by reference in its entirety.

### BACKGROUND

### 1. Field

The present disclosure relates generally to a display device. More particularly, the present disclosure relates to a display device that provides visual information and an electronic device including the same.

### 2. Description of the Related Art

With the development of information technology, the importance of a display device, which is a connection medium between a user and information, has been highlighted. For example, the use of display devices such as liquid crystal display (LCD) device, organic light emitting display (OLED) device, plasma display panel (PDP) device, quantum dot display device or the like is increasing.

A display device may include a display panel which is flexible. The display panel may include a display area for displaying an image, a bending area positioned on one side of the display area, and a pad area spaced apart from the display area with the bending area between the display area and the pad area. A driving chip which drives a pixel may be disposed in the pad area.

In order to reduce the transfer of heat generated by the driving chip to the display panel, a heat dissipating member which dissipates the heat generated by the driving chip may be disposed on a back surface of the display panel. In addition, in order to protect the display panel from an external impact, a buffer member may be disposed on the back surface of the display panel.

### SUMMARY

Embodiments provide a display device including a shielding layer with improved heat dissipation property.

Embodiments provide a display device including an organic layer with improved buffering property.

Embodiments provide an electronic device including the display device.

A display device according to an embodiment of the present disclosure includes: a substrate including a display area and a bending area positioned on one side of the display area, a lower surface of the substrate defining a plurality of openings; a shielding layer disposed along the lower surface of the substrate and continuously extending within the plurality of openings; and a first organic layer disposed under the shielding layer and flattening a lower surface of the shielding layer.

In an embodiment, the shielding layer may define a plurality of grooves overlapping the plurality of openings, respectively. The first organic layer may cover the plurality of grooves.

In an embodiment, the first organic layer may fill the plurality of grooves.

In an embodiment, each of the plurality of grooves may include a pore.

In an embodiment, a first modulus of elasticity of the first organic layer may be smaller than a second modulus of elasticity of the substrate.

In an embodiment, the shielding layer may include at least one of copper, graphite, and carbon nanotube.

In an embodiment, the first organic layer may include an organic material including a light blocking material with a black color.

In an embodiment, the plurality of openings may overlap the display area and be spaced apart from the bending area in a plan view.

In an embodiment, each of the shielding layer and the first organic layer may overlap the display area and be spaced apart from the bending area in a plan view.

In an embodiment, each of the plurality of openings may penetrate the substrate in a thickness direction of the substrate.

In an embodiment, the substrate may further include a pad area spaced apart from the display area in a plan view with the bending area between the pad area and the display area.

In an embodiment, the display device may further include a second organic layer disposed on the lower surface of the substrate and overlapping the pad area in the plan view.

In an embodiment, the second organic layer and the first organic layer may include a same material.

In an embodiment, the second organic layer may include a different material from the first organic layer. A third modulus of elasticity of the second organic layer may be greater than a first modulus of elasticity of the first organic layer.

A display device according to an embodiment of the present disclosure includes: a substrate including a display area and a bending area positioned on one side of the display area, a lower surface of the substrate defining a plurality of openings; a first organic layer disposed under the substrate and covering the plurality of openings; and a shielding layer disposed under the first organic layer and covering a lower surface of the first organic layer.

In an embodiment, the first organic layer may fill the plurality of openings.

In an embodiment, the first organic layer may be disposed outside the plurality of openings, and each of the plurality of openings may include a pore.

In an embodiment, the shielding layer may have a flat upper surface.

In an embodiment, a first modulus of elasticity of the first organic layer may be smaller than a second modulus of elasticity of the substrate.

In an embodiment, the shielding layer may include at least one of copper, graphite, and carbon nanotube.

In an embodiment, the first organic layer may include an organic material including a light blocking material with a black color.

In an embodiment, the plurality of openings may overlap the display area and be spaced apart from the bending area in a plan view.

In an embodiment, each of the shielding layer and the first organic layer may overlap the display area and be spaced apart from the bending area in a plan view.

In an embodiment, each of the plurality of openings may penetrate the substrate in a thickness direction of the substrate.

In an embodiment, the substrate may further include a pad area spaced apart from the display area in a plan view with the bending area between the pad area and the display area.

In an embodiment, the display device may further include a second organic layer disposed on the lower surface of the substrate and overlapping the pad area in the plan view. In an embodiment, the second organic layer and the first organic layer may include a same material.

In an embodiment, the second organic layer may include a different material from the first organic layer. A third modulus of elasticity of the second organic layer may be greater than a first modulus of elasticity of the first organic layer.

An electronic device according to an embodiment of the present disclosure includes: a display panel including a display area and a bending area positioned on one side of the display area, a lower surface of the display panel defining a plurality of openings; a shielding layer disposed along the lower surface of the display panel and continuously extending within the plurality of openings; a first organic layer disposed under the shielding layer and flattening a lower surface of the shielding layer; and a power supply configured to provide power to the display panel.

An electronic device according to an embodiment of the present disclosure includes: a display panel including a display area and a bending area positioned on one side of the display area, a lower surface of the display panel defining a plurality of openings; a first organic layer disposed under the substrate and covering the plurality of openings; a shielding layer disposed under the first organic layer and covering a lower surface of the first organic layer; and a power supply configured to provide power to the display panel.

A display device according to an embodiment of the present disclosure may include a substrate having a plurality of openings defined on its lower surface, a shielding layer disposed along a profile of the lower surface of the substrate and extending continuously within the openings, and a first organic layer disposed under the shielding layer.

As the openings are defined on the lower surface of the substrate, and the shielding layer is disposed along the profile of the lower surface of the substrate, the shielding layer may define a plurality of grooves overlapping the openings, respectively. Accordingly, an area of the shielding layer contacting the substrate may be increased, and a surface area of the shielding layer may be increased. As a result, the shielding layer may effectively dissipate heat generated from a driving chip, and may effectively shield electromagnetic interference noise.

A display device according to an embodiment of the present disclosure may include a substrate having a plurality of openings defined on its lower surface, a first organic layer disposed under the substrate and covering the openings, and a shielding layer disposed under the first organic layer. The first organic layer may fill inside the openings.

A first modulus of elasticity of the first organic layer may be smaller than a second modulus of elasticity of the substrate. As the first organic layer fills inside the openings, the substrate and the first organic layer may be arranged in an order of the substrate, the first organic layer, the substrate, and the first organic layer along one direction. That is, the substrate having the relatively large second modulus of elasticity and the first organic layer having the relatively small first modulus of elasticity may be arranged alternately along the one direction. Accordingly, the first organic layer may effectively protect the substrate from an external impact.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a view illustrating a bent shape of the display device of FIG. 1.

FIG. 3 is a cross-sectional view illustrating the display device of FIG. 1.

FIG. 4 is a cross-sectional view taken along line I-I′ of FIG. 1.

FIG. 5A is a plan view illustrating a substrate of FIG. 3.

FIG. 5B is an enlarged cross-sectional view of area ‘A’ of FIG. 3.

FIG. 6 is a cross-sectional view illustrating a display device according to an embodiment of the present disclosure.

FIG. 7 is an enlarged cross-sectional view of area ‘B’ of FIG. 6.

FIG. 8 is a cross-sectional view illustrating a display device according to an embodiment of the present disclosure.

FIG. 9 is an enlarged cross-sectional view of area ‘C’ of FIG. 8.

FIG. 10 is a cross-sectional view illustrating a display device according to an embodiment of the present disclosure.

FIG. 11 is an enlarged cross-sectional view of area ‘D’ of FIG. 10.

FIG. 12 is a block diagram illustrating an electronic device according to an embodiment of the present disclosure.

FIG. 13 is a view illustrating an example in which the electronic device of FIG. 12 is implemented as a smart phone.

### DETAILED DESCRIPTION OF THE EMBODIMENTS

Hereinafter, embodiments of the present disclosure will be described in detail with reference to the accompanying drawings. The same reference numerals are used for the same components in the drawings, and redundant descriptions of the same components will be omitted.

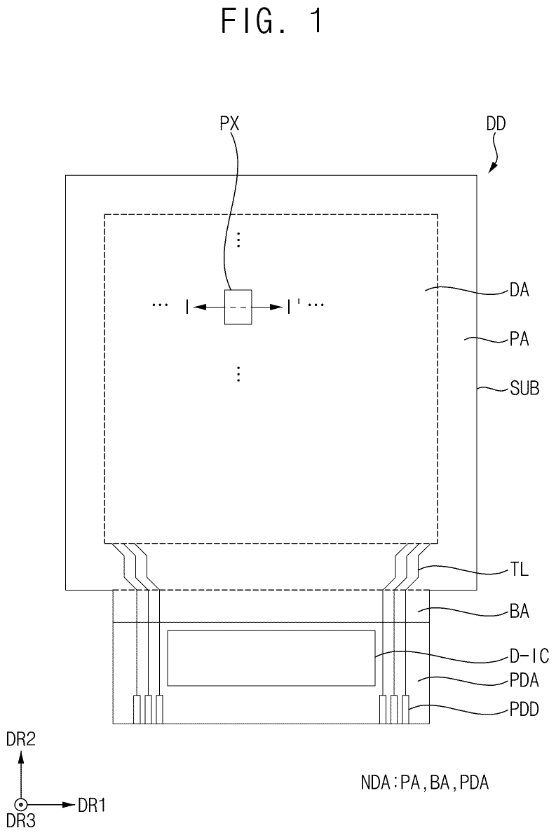

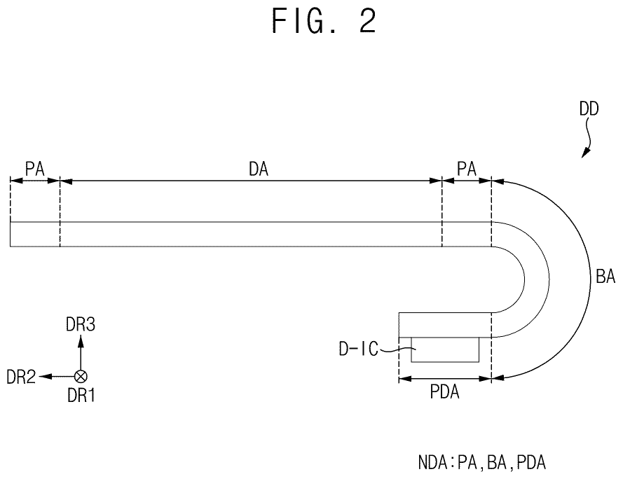

FIG. 1 is a plan view illustrating a display device DD according to an embodiment of the present disclosure. FIG. 2 is a view illustrating a bent shape of the display device DD of FIG. 1.

In this specification, a plane may be defined by a first direction DR1 and a second direction DR2 intersecting the first direction DR1. For example, the first direction DR1 and the second direction DR2 may be perpendicular to each other. A direction normal to the plane, that is, a thickness direction of a display device DD may be a third direction DR3. In other words, the third direction DR3 may be perpendicular to each of the first direction DR1 and the second direction DR2.

Referring to FIGS. 1 and 2, the display device DD according to an embodiment of the present disclosure may include a substrate SUB, a driving chip D-IC, a plurality of transmission lines TL, and a plurality of pads PDD.

The substrate SUB may include a display area DA and a non-display area NDA. The display area DA may be defined as an area that displays an image by generating light or adjusting the transmittance of light provided from an external light source. A plurality of pixels PX may be disposed in the display area DA. Each of the pixels PX may generate light in response to a driving signal. For example, the pixels PX may be arranged in a matrix along the first direction DR1 and the second direction DR2.

The non-display area NDA may be defined as an area that does not display an image. The non-display area NDA may include a peripheral area PA, a bending area BA, and a pad area PDA.

The peripheral area PA may be positioned around the display area DA. The peripheral area PA may surround at least a portion of the display area DA. For example, the peripheral area PA may entirely surround the display area DA in a plan view.

The bending area BA may be positioned on one side of the display area DA. Specifically, the bending area BA may extend from one side of the peripheral area PA and may be bent downward. In other words, as illustrated in FIG. 2, the substrate SUB may be bent about a reference axis parallel to the first direction DR1 in the bending area BA. In this case, the pad area PDA may be positioned on a lower surface of the display device DD. The pad area PDA may extend from the bending area BA and be positioned under the display area DA or the peripheral area PA. When the display device DD is unfolded, the bending area BA may be positioned between the display area DA and the pad area PDA. Specifically, when the display device DD is unfolded, the bending area BA may be positioned between the peripheral area PA and the pad area PDA.

The pad area PDA may be positioned on one side of the display area DA. For example, the pad area PDA and the display area DA may be spaced apart from each other in the second direction DR2. Specifically, the pad area PDA may be spaced from the display area DA in a plan view with the bending area BA between the pad area PDA and the display area DA. The pad area PDA may extend in the first direction DR1. The pads PDD may be disposed in the pad area PDA.

The transmission lines TL may be disposed on the substrate SUB. The transmission lines TL may connect the display area DA and the pad area PDA. Each of the transmission lines TL may include a first end positioned in the pad area PDA and a second end adjacent to the display area DA. The first end of each of the transmission lines TL may be connected to a corresponding pad of the pads PDD. The second end of each of the transmission lines TL may be connected to a corresponding line of a plurality of lines (e.g., gate lines, data lines, driving voltage lines, etc.) disposed in the display area DA. The pads PDD and the pixels PX may be electrically connected through the transmission lines TL.

The driving chip D-IC may be disposed in the pad area PDA on the substrate SUB. The driving chip D-IC may be connected to the pads PDD through an anisotropic conductive film (“ACF”). Specifically, the driving chip D-IC may include a plurality of bumps, and the plurality of bumps may be connected to the pads PDD through the anisotropic conductive film. The driving chip D-IC may provide the driving signal to the pixels PX. The driving signal may include various signals to drive the pixels PX, such as driving voltage, control signals, data signals, etc. The driving signal may be transferred to the pixels PX through the pads PDD and the transmission lines TL.

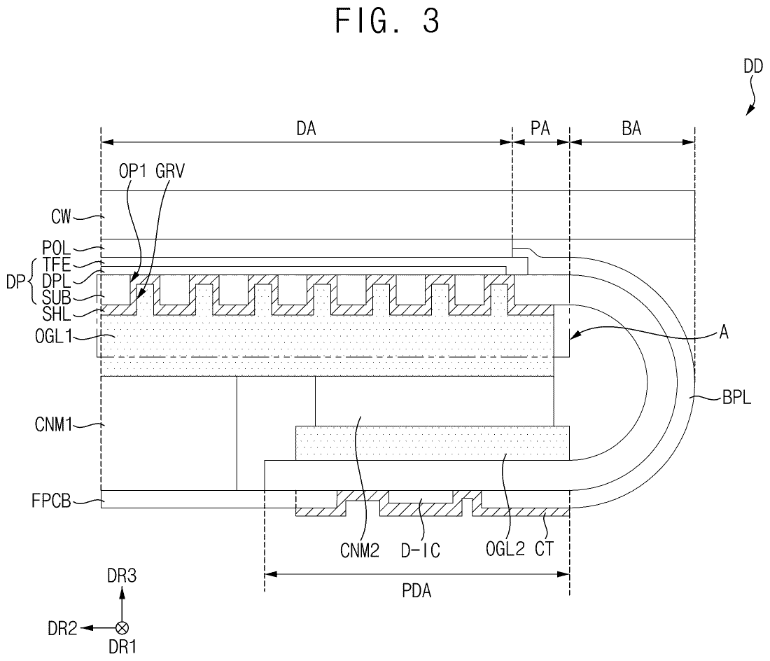

Although not illustrated in FIGS. 1 and 2, a printed circuit board (e.g., a printed circuit board FPCB of FIG. 3) may be disposed in the pad area PDA on the substrate SUB. The printed circuit board may be coupled to the pads PDD through an anisotropic conductive film. For example, the printed circuit board may be a flexible printed circuit board.

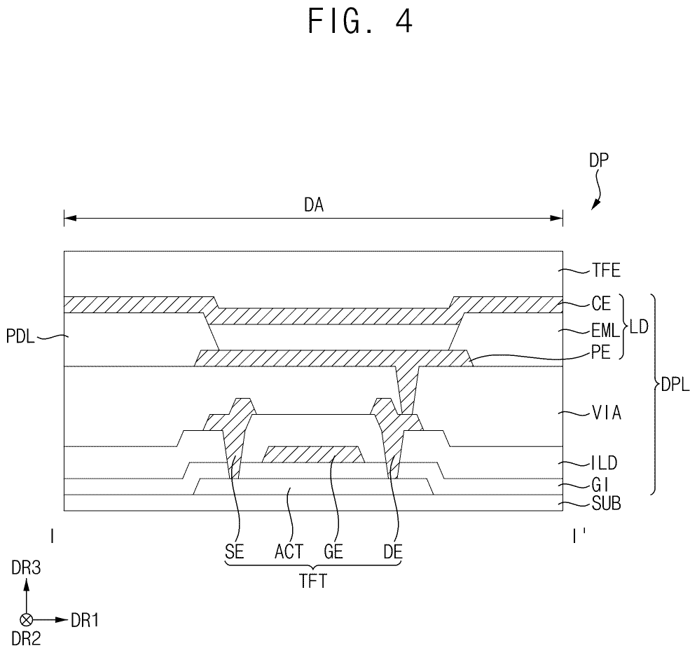

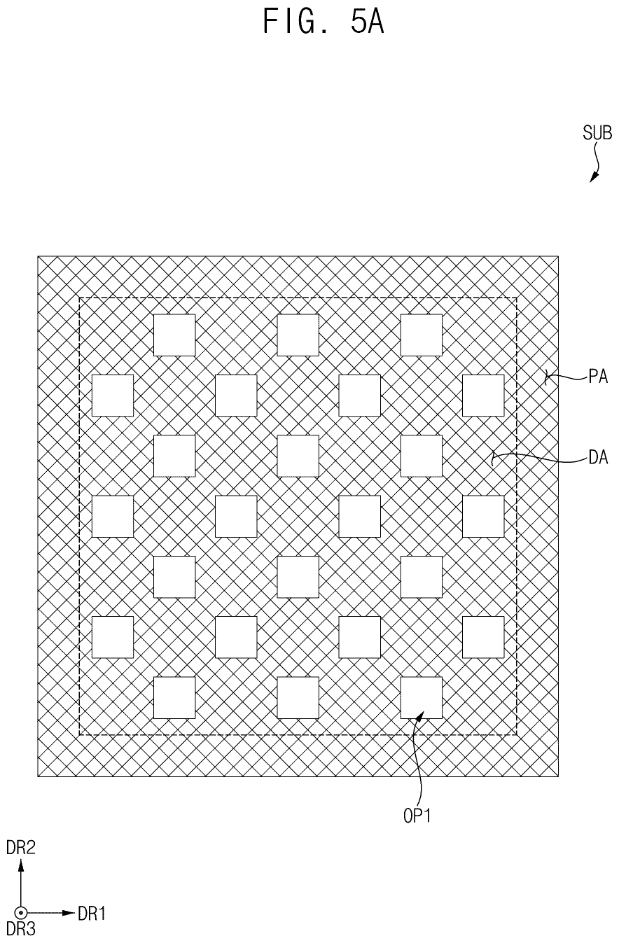

FIG. 3 is a cross-sectional view illustrating the display device DD of FIG. 1. FIG. 4 is a cross-sectional view taken along line I-I′ of FIG. 1. FIG. 5A is a plan view illustrating a substrate of FIG. 3. FIG. 5B is an enlarged cross-sectional view of area ‘A’ of FIG. 3.

Referring to FIGS. 3, 4, 5A and 5B, the display device DD according to an embodiment of the present disclosure may include a cover window CW, an anti-reflection layer POL, a display panel DP, a shielding layer SHL, a first organic layer OGL1, a second organic layer OGL2, a first connecting member CNM1, a second connecting member CNM2, a reinforcing member BPL, the driving chip D-IC, a printed circuit board FPCB, and a cover tape CT. The display panel DP may include the substrate SUB, a display element layer DPL, and an encapsulation layer TFE.

The substrate SUB may include a transparent material or an opaque material. The substrate SUB may be formed of a transparent resin substrate. In an embodiment, the substrate SUB may include a polyimide. In this case, the substrate SUB may include a first organic layer, a first barrier layer, a second organic layer, etc. In an embodiment, the substrate SUB may include a quartz substrate, a synthetic quartz substrate, a calcium fluoride substrate, a fluorine-doped quartz substrate, a soda-lime glass substrate, a non-alkali glass substrate, etc. These may be used alone or in combination with each other.

The display element layer DPL may be disposed in the display area DA on the substrate SUB. Specifically, the display element layer DPL may be disposed on an upper surface of the substrate SUB. As illustrated in FIG. 4, the display element layer DPL may include a thin film transistor TFT, a gate insulating layer GI, an inter-layer insulating layer ILD, a via-insulating layer VIA, a light emitting element LD, and a pixel defining layer PDL. The thin film transistor TFT may include an active pattern ACT, a gate electrode GE, a source electrode SE, and a drain electrode DE. The light emitting element LD may include a pixel electrode PE, a light emitting layer EML, and a common electrode CE.

A buffer layer may be disposed between the substrate SUB and the display element layer DPL. The buffer layer may prevent diffusion of metal atoms or impurities from the substrate SUB to an upper structure (e.g., the thin film transistor TFT, the light emitting element LD, etc.). In addition, the buffer layer may obtain the substantially uniform active pattern ACT by controlling a heat transfer rate during a crystallization process for forming the active pattern ACT. In addition, the buffer layer may serve to improve flatness of a surface of the substrate SUB when the surface of the substrate SUB is not uniform. For example, the buffer layer may include an inorganic insulating material. In an embodiment, the buffer layer may be omitted.

The active pattern ACT may be disposed on the substrate SUB. The active pattern ACT may include an oxide semiconductor, a silicon semiconductor, an organic semiconductor, etc. For example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), zinc (Zn), etc. These may be used alone or in combination with each other. The silicon semiconductor may include amorphous silicon, polycrystalline silicon, etc. The active pattern ACT may include a source area, a drain area, and a channel area positioned between the source area and the drain area.

The gate insulating layer GI may be disposed on the active pattern ACT and the substrate SUB. The gate insulating layer GI may cover the active pattern ACT on the substrate SUB and may be disposed along the profile of the active pattern ACT with a substantially uniform thickness. In an embodiment, the gate insulating layer GI may sufficiently cover the active pattern ACT on the substrate SUB, and may have a substantially flat upper surface without creating a step difference around the active pattern ACT. The gate insulating layer GI may include an inorganic insulating material. Examples of the inorganic insulating material that may be used as the gate insulating layer GI may include silicon oxide (SiOₓ), silicon nitride (SiNₓ), silicon oxynitride (SiOₓN_{y}), etc. These may be used alone or in combination with each other. The gate insulating layer GI may electrically insulate the active pattern ACT from the gate electrode GE.

The gate electrode GE may be disposed on the gate insulating layer GI. The gate electrode GE may overlap the channel area of the active pattern ACT. The gate electrode GE may include a metal, an alloy, a metal nitride, a conductive metal oxide, a transparent conductive material, etc. Examples of material that may be used as the gate electrode GE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These may be used alone or in combination with each other.

The inter-layer insulating layer ILD may be disposed on the gate electrode GE and the gate insulating layer GI. The inter-layer insulating layer ILD may cover the gate electrode GE on the gate insulating layer GI and may be disposed along the profile of the gate electrode GE with a substantially uniform thickness. In an embodiment, the inter-layer insulating layer ILD may sufficiently cover the gate electrode GE on the gate insulating layer GI, and may have a substantially flat upper surface without creating a step difference around the gate electrode GE. The inter-layer insulating layer ILD may include an inorganic insulating material. Examples of the inorganic insulating material that may be used as the inter-layer insulating layer ILD may include silicon oxide (SiOₓ), silicon nitride (SiNₓ), silicon oxynitride (SiOₓN_{y}), etc. These may be used alone or in combination with each other. The inter-layer insulating layer ILD may electrically insulate the gate electrode GE from the source electrode SE. In addition, the inter-layer insulating layer ILD may electrically insulate the gate electrode GE from the drain electrode DE.

The source electrode SE and the drain electrode DE may be disposed on the inter-layer insulating layer ILD. The source electrode SE may be connected to the source area of the active pattern ACT through a contact hole formed through the inter-layer insulating layer ILD and the gate insulating layer GI. The drain electrode DE may be connected to the drain area of the active pattern ACT through a contact hole formed through the inter-layer insulating layer ILD and the gate insulating layer GI. Each of the source electrode SE and the drain electrode DE may include a metal, an alloy, a metal nitride, a conductive metal oxide, a transparent conductive material, etc. These may be used alone or in combination with each other.

Accordingly, the thin film transistor TFT including the active pattern ACT, the gate electrode GE, the source electrode SE, and the drain electrode DE may be formed.

The via-insulating layer VIA may be disposed on the inter-layer insulating layer ILD. For example, the via-insulating layer VIA may be disposed on the inter-layer insulating layer ILD with a relatively thick thickness to sufficiently cover the source electrode SE and the drain electrode DE. The via-insulating layer VIA may include an organic insulating material. Examples of the organic insulating material that may be used as the via-insulating layer VIA may include a photoresist, a polyacryl-based resin, a polyimide-based resin, a polyamide-based resin, a siloxane-based resin, an acryl-based resin, an epoxy-based resin, etc. These may be used alone or in combination with each other.

The pixel electrode PE may be disposed on the via-insulating layer VIA. The pixel electrode PE may be connected to the drain electrode DE through a contact hole formed through the via-insulating layer VIA. Accordingly, the pixel electrode PE may be electrically connected to the thin film transistor TFT. For example, the pixel electrode PE may be a semi-transmissive electrode, a transmissive electrode, or a reflective electrode. The pixel electrode PE may include a metal, an alloy, a metal nitride, a conductive metal oxide, a transparent conductive material, etc. These may be used alone or in combination with each other. For example, the pixel electrode PE may serve as an anode electrode.

The pixel defining layer PDL may be disposed on the via-insulating layer VIA. The pixel defining layer PDL may cover an edge of the pixel electrode PE and may expose a portion of an upper surface of the pixel electrode PE. The pixel defining layer PDL may include an organic insulating material. Examples of the organic insulating material that may be used as the pixel defining layer PDL may include a photoresist, a polyacryl-based resin, a polyimide-based resin, a polyamide-based resin, a siloxane-based resin, an acryl-based resin, an epoxy-based resin, etc. These may be used alone or in combination with each other.

The light emitting layer EML may be disposed on the pixel electrode PE. Specifically, the light emitting layer EML may be disposed on the upper surface of the pixel electrode PE exposed by the pixel defining layer PDL. The light emitting layer EML may emit light having a specific color (e.g., red, green and/or blue). In an embodiment, the light emitting layer EML may include one or both of an organic light emitting material and a quantum dot. For example, the light emitting layer EML may include an organic light emitting material including a fluorescent or phosphorescent material that emits red, green, blue, or white light. The quantum dot may be a particle having a crystal structure of several to tens of nanometers in size, and may include hundreds to thousands of atoms. The quantum dot may include a fluorescent material or a phosphorescent material, and may produce monochromatic red, green, and blue light.

For example, the light emitting layer EML may have a single-layer structure including one light emitting layer. In an embodiment, the light emitting layer EML may have a tandem structure in which a plurality of light emitting layers are stacked.

The common electrode CE may be disposed on the pixel defining layer PDL and the light emitting layer EML. The common electrode CE may be disposed along the profiles of the pixel defining layer PDL and the light emitting layer EML with a substantially uniform thickness. In an embodiment, the common electrode CE may include a metal, an alloy, a metal nitride, a conductive metal oxide, a transparent conductive material, etc. These may be used alone or in combination with each other. For example, the common electrode CE may serve as a cathode electrode.

Accordingly, the light emitting element LD including the pixel electrode PE, the light emitting layer EML, and the common electrode CE may be formed.

The encapsulation layer TFE may be disposed on the common electrode CE. The encapsulation layer TFE may prevent impurities, moisture, etc. from penetrating into the light emitting element LD from the outside. The encapsulation layer TFE may include at least one inorganic encapsulation layer and at least one organic encapsulation layer. For example, the inorganic encapsulation layer may include silicon oxide (SiOₓ), silicon nitride (SiNₓ), silicon oxynitride (SiOₓN_{y}), etc. These may be used alone or in combination with each other. For example, the organic encapsulation layer may include a cured polymer such as polyacrylate.

The encapsulation layer TFE may have a structure in which the inorganic encapsulation layer and the organic encapsulation layer are alternately stacked. For example, the encapsulation layer TFE may have a three-layer structure with two inorganic encapsulation layers and one organic encapsulation layer alternately stacked with each other. However, the present disclosure is not limited thereto, and the encapsulation layer TFE may have a five-layer structure with three inorganic encapsulation layers and two organic encapsulation layers alternatively stacked with each other, or the encapsulation layer TFE may have a seven-layer structure with four inorganic encapsulation layers and three organic encapsulation layers alternatively stacked with each other.

Although the display device DD of the present disclosure is described as an organic light emitting display (“OLED”) device, the configuration of the present disclosure is not limited thereto. In other embodiments, the display device DD may include a liquid crystal display (“LCD”) device, a field emission display (“FED”) device, a plasma display panel (“PDP”) device, an electrophoretic image display (“EPD”) device, an inorganic light emitting display (“ILED”) device, or a quantum dot display device.

As illustrated in FIG. 3, the anti-reflection layer POL may be disposed in the display area DA on the display panel DP. Specifically, the anti-reflection layer POL may be disposed on the encapsulation layer TFE. The anti-reflection layer POL may reduce the external light reflection of the display device DD. As the external light reflection is reduced, the visibility of the display device DD may be improved. The anti-reflection layer POL may include a polarizer and/or a phase retarder. For example, the anti-reflection layer POL may include a polarizer and/or a phase retarder of a stretchable film type.

In an embodiment, the anti-reflection layer POL may include color filters and a black matrix disposed between the color filters. The color filters may have a predetermined arrangement. The color filters may be arranged in consideration of a light emitting color of the light emitting element LD included in the display element layer DPL.

The cover window CW may be disposed on the anti-reflection layer POL. The cover window CW may serve to cover and protect the display panel DP. The cover window CW may be attached to an upper surface of the anti-reflection layer POL through an adhesive member. For example, the adhesive member may be a pressure sensitive adhesive (“PSA”) film, an optically clear adhesive (“OCA”) film, an optically clear resin (“OCR”), etc.

The reinforcing member BPL may be disposed in the bending area BA on the substrate SUB. The reinforcing member BPL may cover the substrate SUB in the bending area BA. In addition, the reinforcing member BPL may extend to cover the substrate SUB in a portion of the peripheral area PA and a portion of the pad area PDA.

The reinforcing member BPL may protect the transmission lines TL, see FIG. 1, from an external impact. In addition, the reinforcing member BPL may complement the rigidity of the substrate SUB in the bending area BA. The reinforcing member BPL may include an organic material. Examples of the organic material that may be used as the reinforcing member BPL may include a polyacrylic-based resin, a polyimide-based resin, a polyamide-based resin, a siloxane-based resin, an acrylic-based resin, an epoxy-based resin, etc. These may be used alone or in combination with each other.

The driving chip D-IC may be disposed in the pad area PDA on the substrate SUB. The driving chip D-IC may be connected to the pads PDD, e.g., see FIG. 1, which are disposed in the pad area PDA on the substrate SUB through an anisotropic conductive film. The driving chip D-IC may provide a driving signal to the display panel DP. The driving signal may include various signals to drive the display panel DP, such as a driving voltage, a control signal, a data signal, etc.

The printed circuit board FPCB may be disposed in the pad area PDA on the substrate SUB. The printed circuit board FPCB may be coupled to the pads through an anisotropic conductive film. For example, the printed circuit board FPCB may be a flexible printed circuit board.

The cover tape CT may be disposed in the pad area PDA on the substrate SUB. The cover tape CT may cover the printed circuit board FPCB, the driving chip D-IC, and the reinforcing member BPL. The cover tape CT may protect the driving chip D-IC from an external impact. In addition, the cover tape CT may include a metal so that heat generated from the driving chip D-IC may be dissipated. For example, the cover tape CT may include copper (Cu) or aluminum (Al).

A plurality of first openings OP1 may be defined on a lower surface of the substrate SUB. In other words, the first openings OP1 may be formed by removing a portion of the lower surface of the substrate SUB. The first openings OP1 may be within and overlap the display area DA and be spaced apart from the bending area BA in a plan view.

That is, the first openings OP1 may be formed on the lower surface of the substrate SUB in the display area DA, and may not be formed on the lower surface of the substrate SUB in the bending area BA and the pad area PDA. In an embodiment, the first openings OP1 may be formed on the lower surface of the substrate SUB in a portion of the peripheral area PA.

In an embodiment, as illustrated in FIG. 3, each of the first openings OP1 may penetrate and extend entirely through the substrate SUB in a thickness direction of the substrate SUB (or, the third direction DR3). In this case, a portion of the display element layer DPL may be exposed by the first openings OP1. However, the present disclosure is not limited thereto.

In other embodiments, each of the first openings OP1 may not penetrate entirely through the substrate SUB in the thickness direction of the substrate SUB. In this case, a plurality of grooves may be defined on the lower surface of the substrate SUB. Each of the grooves may refer to a portion of the lower surface of the substrate SUB being depressed toward the display element layer DPL.

In an embodiment, as illustrated in FIG. 5A, the first openings OP1 may be arranged in a zigzag shape in a plan view. However, a shape in which the first openings OP1 are arranged in a plan view is not limited thereto, and the first openings OP1 may be arranged in various shapes in a plan view. For example, the first openings OP1 may include a plurality of groups arranged in a line along the first direction DR1 in a plan view, and the plurality of groups may be arranged along the second direction DR2.

The shielding layer SHL may be disposed under the substrate SUB. Specifically, the shielding layer SHL may be disposed along the profile of the lower surface of the substrate SUB with a substantially uniform thickness. The shielding layer SHL may extend continuously within the first openings OP1.

The shielding layer SHL may include a metal, an alloy, a metal nitride, a conductive metal oxide, a transparent conductive material, etc. These may be used alone or in combination with each other. In an embodiment, the shielding layer SHL may include copper (Cu) or aluminum (Al). Accordingly, the shielding layer SHL may dissipate heat generated from the driving chip D-IC. As a result, the heat transferred from the driving chip D-IC to the display element layer DPL may be reduced. In addition, the shielding layer SHL may shield electromagnetic interference (“EMI”) noise. That is, the shielding layer SHL may serve a heat dissipation function and a shielding function.

In an embodiment, the shielding layer SHL may include graphite or carbon nanotube. In this case, the shielding layer SHL may reduce the external light reflection of the display device DD and may improve the visibility of the display device DD. That is, the shielding layer SHL may serve a heat dissipation function, a shielding function, and a light blocking function.

As the first openings OP1 are defined on the lower surface of the substrate SUB, and the shielding layer SHL is disposed along the profile of the lower surface of the substrate SUB, the shielding layer SHL may define a plurality of grooves GRV overlapping the first openings OP1, respectively. In other words, the shielding layer SHL may include an uneven pattern. As the shielding layer SHL includes the uneven pattern, an area of the shielding layer SHL contacting the substrate SUB may be increased, and a surface area of the shielding layer SHL may be increased. Accordingly, the shielding layer SHL may effectively dissipate heat generated from the driving chip D-IC and may effectively shield electromagnetic interference noise. That is, the heat dissipation property and the shielding property of the shielding layer SHL may be improved by increasing the surface area of the shielding layer SHL. As the heat dissipation property and the shielding property of the shielding layer SHL are improved, the shielding layer SHL may be formed with a relatively small thickness. For example, the shielding layer SHL may have a thickness of about 35 micrometers or less. However, the present disclosure is not limited thereto.

The first organic layer OGL1 may be disposed under the shielding layer SHL. The first organic layer OGL1 may flatten a lower surface of the shielding layer SHL. Specifically, the first organic layer OGL1 may sufficiently cover the lower surface of the shielding layer SHL, and may have a substantially flat lower surface.

The first organic layer OGL1 may protect the substrate SUB from an external impact. In other words, the first organic layer OGL1 may complement the rigidity of the substrate SUB by cushioning the external impact. The first organic layer OGL1 may maintain a portion of the substrate SUB which overlaps the display area DA in a flat state. The first organic layer OGL1 may include an adhesive material having insulating properties. For example, the first organic layer OGL1 may include a thermoplastic resin and/or a thermosetting resin. Examples of the thermoplastic resin that may be used as the first organic layer OGL1 may include an acrylic-based resin, a vinyl-based resin, a polyolefin-based resin, a polycarbonate-based resin, etc. They may be used alone or in combination with each other. Examples of the thermosetting resin that may be used as the first organic layer OGL1 may include an epoxy-based resin, a phenolic resin, a melamine-based resin, etc. They may be used alone or in combination with each other.

The first organic layer OGL1 may cover the grooves GRV defined by the shielding layer SHL. In an embodiment, the first organic layer OGL1 may fill the grooves GRV. As the first organic layer OGL1 fills the grooves GRV, an area of the first organic layer OGL1 contacting the shielding layer SHL may be increased, and a surface area of the first organic layer OGL1 may be increased. Accordingly, the adhesion between the first organic layer OGL1 and the shielding layer SHL may be increased. As a result, the first organic layer OGL1 may be prevented from being delaminated from the shielding layer SHL when the substrate SUB is bent.

In an embodiment, a first modulus of elasticity of the first organic layer OGL1 may be smaller than a second modulus of elasticity of the substrate SUB. For example, the first modulus of elasticity of the first organic layer OGL1 may be about 0.01 MPa to about 1 MPa. As the first organic layer OGL1 fills the grooves GRV, as illustrated in FIGS. 3 and 5B, the substrate SUB and the first organic layer OGL1 may be arranged in an order of the substrate SUB, the first organic layer OGL1, the substrate SUB, and the first organic layer OGL1 along the second direction DR2. In other words, the substrate SUB and the first organic layer OGL1 may be arranged alternately along the second direction DR2. That is, the substrate SUB having the relatively large second modulus of elasticity and the first organic layer OGL1 having the relatively small first modulus of elasticity may be arranged alternately along the second direction DR2. Accordingly, the first organic layer OGL1 may effectively protect the substrate SUB from an external impact. That is, the buffering property of the first organic layer OGL1 and the property of complementing the rigidity of the substrate SUB of the first organic layer OGL1 may be improved.

In an embodiment, the first organic layer OGL1 may include an organic material including a light blocking material with a black color. In this case, the first organic layer OGL1 may reduce the external light reflection of the display device DD and improve the visibility of the display device DD. That is, the first organic layer OGL1 may serve a light blocking function. For example, the light blocking material may include a black pigment, a black dye, carbon black, etc. They may be used alone or in combination with each other.

The shielding layer SHL and the first organic layer OGL1 may overlap the display area DA, and may not overlap the bending area BA in a plan view. In other words, the shielding layer SHL and the first organic layer OGL1 may be disposed under the substrate SUB in the display area DA, and may not be disposed under the substrate SUB in the bending area BA and the pad area PDA.

The second organic layer OGL2 may be disposed on the lower surface of the substrate SUB, and may overlap the pad area PDA in a plan view. The first openings OP1 may not be formed on the lower surface of the substrate SUB on which the second organic layer OGL2 is disposed. The second organic layer OGL2 may complement the rigidity of the substrate SUB. The second organic layer OGL2 may maintain a portion of the substrate SUB which overlaps the pad area PDA in a flat state. Examples of an organic material that may be used as the second organic layer OGL2 may include a polyacrylic-based resin, a polyimide-based resin, a polyamide-based resin, a siloxane-based resin, an acrylic-based resin, an epoxy-based resin, etc. These may be used alone or in combination with each other.

In an embodiment, the second organic layer OGL2 may include the same material as the first organic layer OGL1. In this case, a third modulus of elasticity of the second organic layer OGL2 may be the same as the first modulus of elasticity of the first organic layer OGL1. For example, the third modulus of elasticity of the second organic layer OGL2 may be about 0.01 MPa to about 1 MPa. However, the present disclosure is not limited thereto.

In other embodiments, the second organic layer OGL2 may include a different material from the first organic layer OGL1. For example, the second organic layer OGL2 may include polyethylene terephthalate (“PET”), polyimide (“PI”), polyethylene naphthalate (“PEN”), etc. They may be used alone or in combination with each other. In this case, the third modulus of elasticity of the second organic layer OGL2 may be greater than the first modulus of elasticity of the first organic layer OGL1. For example, the third modulus of elasticity of the second organic layer OGL2 may be about 4 GPa.

The first connecting member CNM1 may be disposed under the first organic layer OGL1. Specifically, the first connecting member CNM1 may be disposed between the first organic layer OGL1 and the printed circuit board FPCB. The first connecting member CNM1 may directly contact the first organic layer OGL1 and the printed circuit board FPCB and may fix the printed circuit board FPCB.

The second connecting member CNM2 may be disposed under the first organic layer OGL1. Specifically, the second connecting member CNM2 may be disposed between the first organic layer OGL1 and the second organic layer OGL2. The second connecting member CNM2 may contact the first organic layer OGL1 and the second organic layer OGL2 and may maintain the substrate SUB in a bent state. In other words, the second connecting member CNM2 may maintain a portion of the substrate SUB which overlaps the bending area BA in a bent state.

In an embodiment, each of the first connecting member CNM1 and the second connecting member CNM2 may include a metal so that heat generated from the driving chip D-IC may be dissipated. In this case, each of the first connecting member CNM1 and the second connecting member CNM2 may include an upper adhesive layer, a lower adhesive layer, and a metal layer disposed between the upper adhesive layer and the lower adhesive layer. For example, the metal layer may include copper (Cu) or aluminum (Al).

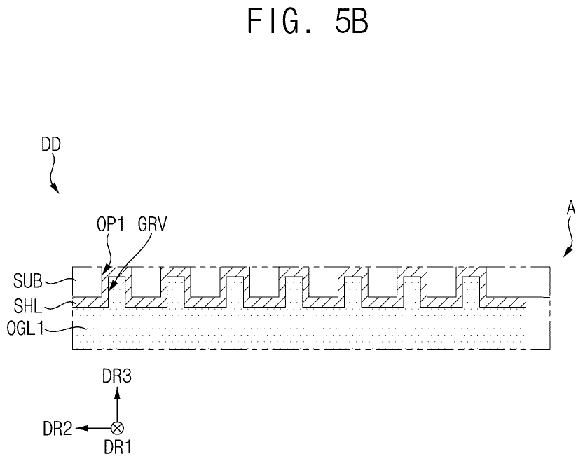

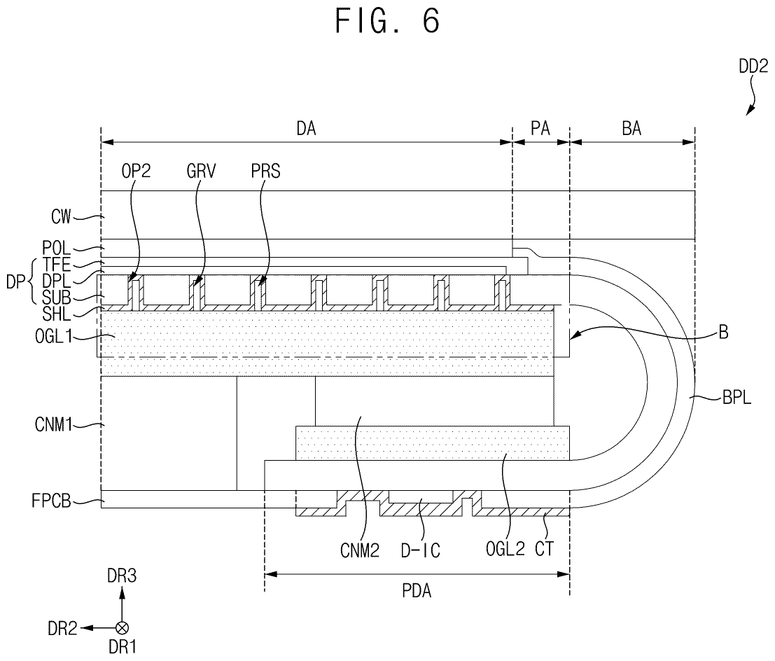

FIG. 6 is a cross-sectional view illustrating a display device DD2 according to an embodiment of the present disclosure. FIG. 7 is an enlarged cross-sectional view of area ‘B’ of FIG. 6.

Referring to FIGS. 6 and 7, the display device DD2 according to an embodiment of the present disclosure may include the cover window CW, the anti-reflection layer POL, a display panel DP, a shielding layer SHL, a first organic layer OGL1, the second organic layer OGL2, the first connecting member CNM1, the second connecting member CNM2, the reinforcing member BPL, the driving chip D-IC, the printed circuit board FPCB, and the cover tape CT. The display panel DP may include a substrate SUB, the display element layer DPL, and the encapsulation layer TFE.

The display device DD2 may be substantially the same as the display device DD described above with reference to FIGS. 1, 2, 3, 4, 5A, and 5B, except that the first organic layer OGL1 may not fill grooves GRV of the shielding layer SHL, and each of the grooves GRV may include a pore PRS. Hereinafter, redundant descriptions of the display device DD described above with reference to FIGS. 1, 2, 3, 4, 5A, and 5B may not be repeated or may be simplified.

A plurality of second openings OP2 may be defined on a lower surface of the substrate SUB. In other words, the second openings OP2 may be formed by removing a portion of the lower surface of the substrate SUB. The second openings OP2 may be within and overlap the display area DA and be spaced apart from the bending area BA in a plan view. That is, the second openings OP2 may be formed on the lower surface of the substrate SUB in the display area DA, and may not be formed on the lower surface of the substrate SUB in the bending area BA and the pad area PDA. In an embodiment, a size of each second opening OP2 may be smaller than a size of each first opening OP1 of FIG. 3. Here, the size of each opening may refer to a length in the second direction DR2 of each opening.

In an embodiment, as illustrated in FIG. 6, each of the second openings OP2 may penetrate entirely through the substrate SUB in the thickness direction of the substrate SUB. In this case, a portion of the display element layer DPL may be exposed by the second openings OP2. However, the present disclosure is not limited thereto.

In other embodiments, each of the second openings OP2 may not penetrate entirely through the substrate SUB in the thickness direction of the substrate SUB. In this case, a plurality of grooves may be defined on the lower surface of the substrate SUB. Each of the grooves may refer to a portion of the lower surface of the substrate SUB being depressed toward the display element layer DPL.

The shielding layer SHL may be disposed under the substrate SUB. Specifically, the shielding layer SHL may be disposed along the profile of the lower surface of the substrate SUB with a substantially uniform thickness. The shielding layer SHL may continuously extend within the second openings OP2. The shielding layer SHL may dissipate heat generated from the driving chip D-IC. In addition, the shielding layer SHL may shield electromagnetic interference noise.

As the second openings OP2 are defined on the lower surface of the substrate SUB, and the shielding layer SHL is disposed along the profile of the lower surface of the substrate SUB, the shielding layer SHL may define a plurality of grooves GRV overlapping the second openings OP2, respectively. In other words, the shielding layer SHL may include an uneven pattern. As the shielding layer SHL includes the uneven pattern, an area of the shielding layer SHL contacting the substrate SUB may be increased, and a surface area of the shielding layer SHL may be increased. Accordingly, the shielding layer SHL may effectively dissipate heat generated from the driving chip D-IC and may effectively shield electromagnetic interference noise. That is, the heat dissipation property and the shielding property of the shielding layer SHL may be improved by increasing the surface area of the shielding layer SHL. As the heat dissipation property and the shielding property of the shielding layer SHL are improved, the shielding layer SHL may be formed with a relatively small thickness.

The first organic layer OGL1 may be disposed under the shielding layer SHL. The first organic layer OGL1 may flatten a lower surface of the shielding layer SHL. Specifically, the first organic layer OGL1 may sufficiently cover the lower surface of the shielding layer SHL, and may have a substantially flat lower surface.

The first organic layer OGL1 may protect the substrate SUB from an external impact. In other words, the first organic layer OGL1 may complement the rigidity of the substrate SUB by cushioning the external impact. The first organic layer OGL1 may maintain a portion of the substrate SUB which overlaps the display area DA in a flat state.

The first organic layer OGL1 may cover the grooves GRV defined by the shielding layer SHL. In an embodiment, the first organic layer OGL1 may not fill the grooves GRV. In other words, the first organic layer OGL1 may not be disposed inside the grooves GRV, and each of the grooves GRV may include the pore PRS. Here, the pore PRS may refer to an air-filled space positioned between the shielding layer SHL and the first organic layer OGL1. The pore PRS may have a square cross-sectional shape, but the present disclosure is not limited thereto.

When an impact is applied to the display device DD2 from the outside, an upper surface of the first organic layer OGL1 contacting the pore PRS may elastically change its shape. That is, the first organic layer OGL1 and the pore PRS may effectively protect the substrate SUB from an external impact. In other words, as each of the grooves GRV includes the pore PRS, the buffering property of the first organic layer OGL1 and the property of complementing the rigidity of the substrate SUB of the first organic layer OGL1 may be improved.

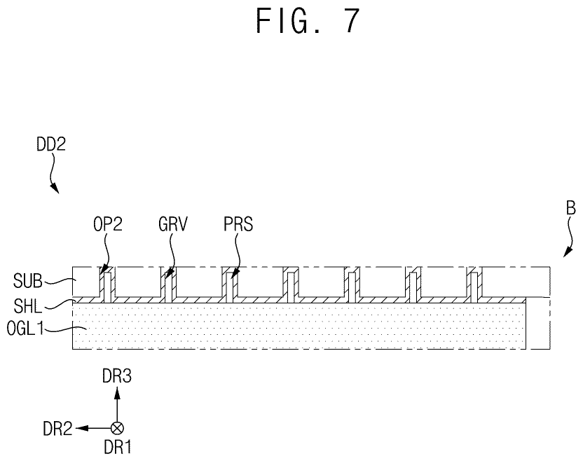

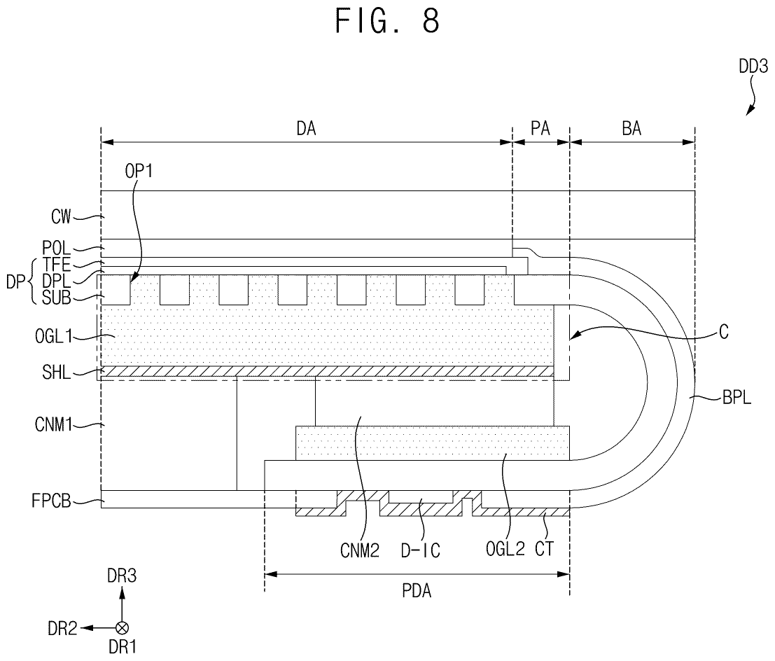

FIG. 8 is a cross-sectional view illustrating a display device DD3 according to an embodiment of the present disclosure. FIG. 9 is an enlarged cross-sectional view of area ‘C’ of FIG. 8.

Referring to FIGS. 8 and 9, the display device DD3 according to an embodiment of the present disclosure may include the cover window CW, the anti-reflection layer POL, a display panel DP, a shielding layer SHL, a first organic layer OGL1, the second organic layer OGL2, the first connecting member CNM1, the second connecting member CNM2, the reinforcing member BPL, the driving chip D-IC, the printed circuit board FPCB, and the cover tape CT. The display panel DP may include a substrate SUB, the display element layer DPL, and the encapsulation layer TFE.

The display device DD3 may be substantially the same as the display device DD described above with reference to FIGS. 1, 2, 3, 4, 5A, and 5B, except that the first organic layer OGL1 may be disposed on a lower surface of the substrate SUB, and the shielding layer SHL may be disposed on a lower surface of the first organic layer OGL1. Hereinafter, redundant descriptions of the display device DD described above with reference to FIGS. 1, 2, 3, 4, 5A and 5B may not be repeated or may be simplified.

A plurality of first openings OP1 may be defined on the lower surface of the substrate SUB. In other words, the first openings OP1 may be formed by removing a portion of the lower surface of the substrate SUB. The first openings OP1 may be within and overlap the display area DA and be spaced apart from the bending area BA in a plan view. That is, the first openings OP1 may be formed on the lower surface of the substrate SUB in the display area DA, and may not be formed on the lower surface of the substrate SUB in the bending area BA and the pad area PDA.

In an embodiment, as illustrated in FIG. 8, each of the first openings OP1 may penetrate entirely through the substrate SUB in the thickness direction of the substrate SUB. In this case, a portion of the display element layer DPL may be exposed by the first openings OP1. However, the present disclosure is not limited thereto.

In other embodiments, each of the first openings OP1 may not penetrate entirely through the substrate SUB in the thickness direction of the substrate SUB. In this case, a plurality of grooves may be defined on the lower surface of the substrate SUB. Each of the grooves may refer to a portion of the lower surface of the substrate SUB depressed toward the display element layer DPL.

The first organic layer OGL1 may be disposed under the substrate SUB. Specifically, the first organic layer OGL1 may be disposed on the lower surface of the substrate SUB, and may cover the first openings OP1. The first organic layer OGL1 may sufficiently cover the lower surface of the substrate SUB, and may have a substantially flat lower surface.

The first organic layer OGL1 may protect the substrate SUB from an external impact. In other words, the first organic layer OGL1 may complement the rigidity of the substrate SUB by cushioning the external impact. The first organic layer OGL1 may maintain a portion of the substrate SUB which overlaps the display area DA in a flat state.

In an embodiment, the first organic layer OGL1 may fill inside the first openings OP1. As the first organic layer OGL1 fills inside the first openings OP1, an area of the first organic layer OGL1 contacting the substrate SUB may be increased, and a surface area of the first organic layer OGL1 may be increased. Accordingly, the adhesion between the first organic layer OGL1 and the substrate SUB may be increased. As a result, the first organic layer OGL1 may be prevented from being delaminated from the substrate SUB when the substrate SUB is bent.

In an embodiment, a first modulus of elasticity of the first organic layer OGL1 may be smaller than a second modulus of the substrate SUB. For example, the first modulus of elasticity of the first organic layer OGL1 may be about 0.01 MPa to about 1 MPa. As the first organic layer OGL1 fills inside the first openings OP1, as illustrated in FIGS. 8 and 9, the substrate SUB and the first organic layer OGL1 may be arranged in an order of the substrate SUB, the first organic layer OGL1, the substrate SUB, and the first organic layer OGL1 along the second direction DR2. In other words, the substrate SUB and the first organic layer OGL1 may be arranged alternately along the second direction DR2. That is, the substrate SUB having the relatively large second modulus and the first organic layer OGL1 having the relatively small first modulus of elasticity may be arranged alternately along the second direction DR2. Accordingly, the first organic layer OGL1 may effectively protect the substrate SUB from an external impact. That is, the buffering property of the first organic layer OGL1 and the property of complementing the rigidity of the substrate SUB of the first organic layer OGL1 may be improved.

The shielding layer SHL may be disposed under the first organic layer OGL1. Specifically, the shielding layer SHL may be disposed on the lower surface of the first organic layer OGL1, and may cover the lower surface of the first organic layer OGL1. The shielding layer SHL may dissipate heat generated from the driving chip D-IC. In addition, the shielding layer SHL may shield electromagnetic interference noise.

As the first organic layer OGL1 has the flat lower surface, the shielding layer SHL disposed on the lower surface of the first organic layer OGL1 may have a flat upper surface. That is, compared to the display device DD according to an embodiment of the present disclosure, wherein the display device DD may include the shielding layer SHL defining the grooves GRV, the display device DD3 according to an embodiment of the present disclosure may include the shielding layer SHL having the flat upper surface.

The first connecting member CNM1 may be disposed under the shielding layer SHL. Specifically, the first connecting member CNM1 may be disposed between the shielding layer SHL and the printed circuit board FPCB. The first connecting member CNM1 may contact the shielding layer SHL and the printed circuit board FPCB and may fix the printed circuit board FPCB.

The second connecting member CNM2 may be disposed under the shielding layer SHL. Specifically, the second connecting member CNM2 may be disposed between the shielding layer SHL and the second organic layer OGL2. The second connecting member CNM2 may contact the shielding layer SHL and the second organic layer OGL2 and may maintain the substrate in a bent state. In other words, the second connecting member CNM2 may maintain a portion of the substrate SUB which overlaps the bending area BA in a bent state.

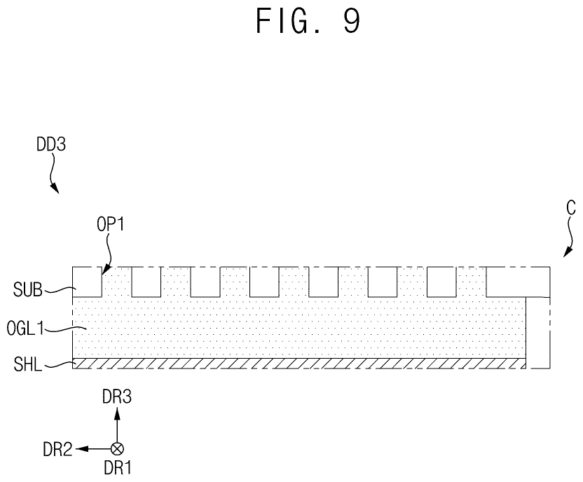

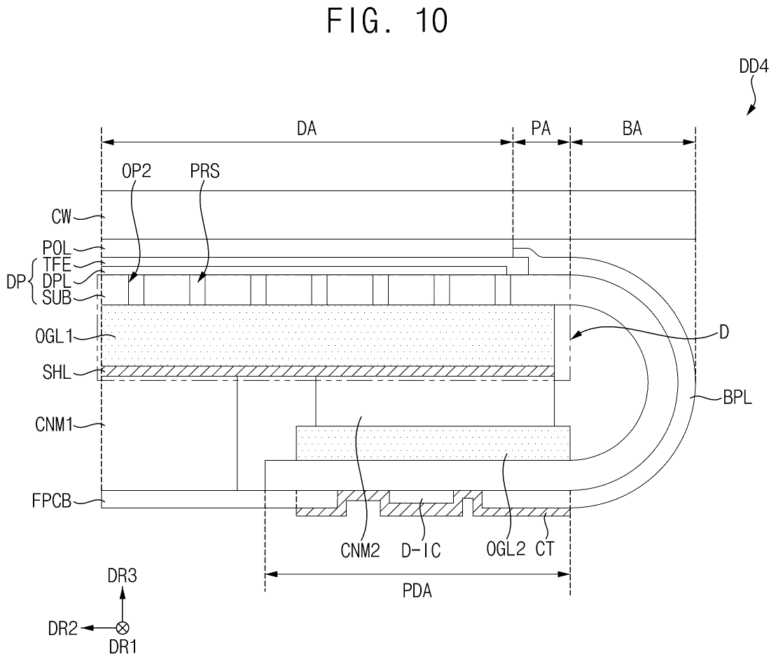

FIG. 10 is a cross-sectional view illustrating a display device DD4 according to an embodiment of the present disclosure. FIG. 11 is an enlarged cross-sectional view of area ‘D’ of FIG. 10.

Referring to FIGS. 10 and 11, the display device DD4 according to an embodiment of the present disclosure may include the cover window CW, the anti-reflection layer POL, a display panel DP, the shielding layer SHL, a first organic layer OGL1, the second organic layer OGL2, the first connecting member CNM1, the second connecting member CNM2, the reinforcing member BPL, the driving chip D-IC, the printed circuit board FPCB, and the cover tape CT. The display panel DP may include a substrate SUB, the display element layer DPL, and the encapsulation layer TFE.

The display device DD4 may be substantially the same as the display device DD3 described above with reference to FIGS. 8 and 9, except that the first organic layer OGL1 may not fill inside second openings OP2, and each of the second openings OP2 may include a pore PRS. Hereinafter, redundant descriptions of the display device DD3 described above with reference to FIGS. 8 and 9 may not be repeated or may be simplified.

The plurality of second openings OP2 may be defined on a lower surface of the substrate SUB. In other words, the second openings OP2 may be formed by removing a portion of the lower surface of the substrate SUB. The second openings OP2 may be within and overlap the display area DA and be spaced apart from the bending area BA in a plan view. That is, the second openings OP2 may be formed on the lower surface of the substrate SUB in the display area DA, and may not be formed on the lower surface of the substrate SUB in the bending area BA and the pad area PDA. In an embodiment, a size of each second opening OP2 may be smaller than a size of each first opening OP1 of FIG. 8. Here, the size of each opening may refer to a length in the second direction DR2 of each opening.

In an embodiment, as illustrated in FIG. 10, each of the second openings OP2 may penetrate entirely through the substrate SUB in the thickness direction of the substrate SUB. In this case, a portion of the display element layer DPL may be exposed by the second openings OP2. However, the present disclosure is not limited thereto.

In other embodiments, each of the second openings OP2 may not penetrate entirely through the substrate SUB in the thickness direction of the substrate SUB. In this case, a plurality of grooves may be defined on the lower surface of the substrate SUB. Each of the grooves may refer to a portion of the lower surface of the substrate SUB being depressed toward the display element layer DPL.

The first organic layer OGL1 may be disposed under the substrate SUB. Specifically, the first organic layer OGL1 may be disposed on the lower surface of the substrate SUB, and may cover the second opening OP2. The first organic layer OGL1 may sufficiently cover the lower surface of the substrate SUB, and may have a substantially flat lower surface.

The first organic layer OGL1 may protect the substrate SUB from an external impact. In other words, the first organic layer OGL1 may complement the rigidity of the substrate SUB by cushioning the external impact. The first organic layer OGL1 may maintain a portion of the substrate SUB which overlaps the display area DA in a flat state.

In an embodiment, the first organic layer OGL1 may be disposed outside the second openings OP2. In other words, the first organic layer OGL1 may not be disposed inside the second openings OP2, and each of the second openings OP2 may include the pore PRS. Here, the pore PRS may refer to an air-filled space positioned between the substrate SUB and the first organic layer OGL1. The pore PRS may have a square cross-sectional shape, but the present disclosure is not limited thereto.

When an impact is applied to the display device DD4 from the outside, an upper surface of the first organic layer OGL1 contacting the pore PRS may elastically change its shape. That is, the first organic layer OGL1 and the pore PRS may effectively protect the substrate SUB from an external impact. In other words, as each of the second openings OP2 includes the pore PRS, the buffering property of the first organic layer OGL1 and the property of complementing the rigidity of the substrate SUB of the first organic layer OGL1 may be improved.

The shielding layer SHL may be disposed under the first organic layer OGL1. Specifically, the shielding layer SHL may be disposed on the lower surface of the first organic layer OGL1, and may cover the lower surface of the first organic layer OGL1. The shielding layer SHL may dissipate heat generated from the driving chip D-IC. In addition, the shielding layer SHL may shield electromagnetic interference noise. As the first organic layer OGL1 has the flat lower surface, the shielding layer SHL disposed on the lower surface of the first organic layer OGL1 may have a flat upper surface.

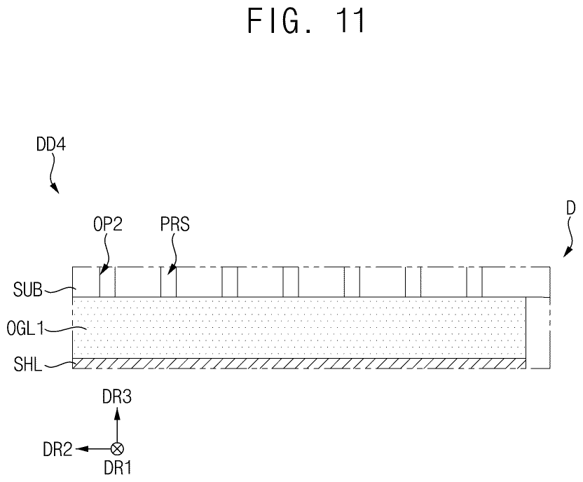

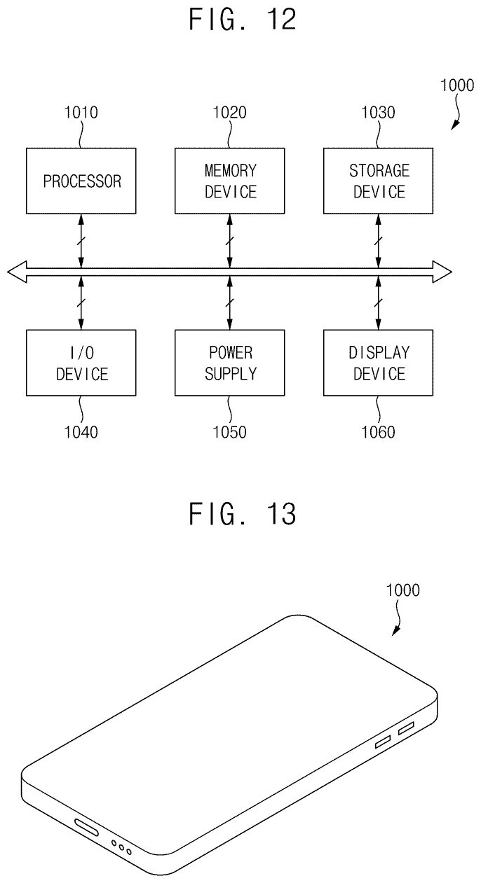

FIG. 12 is a block diagram illustrating an electronic device according to an embodiment of the present disclosure. FIG. 13 is a view illustrating an example in which the electronic device of FIG. 12 is implemented as a smart phone.

Referring to FIGS. 12 and 13, an electronic device 1000 may include a processor 1010, a memory device 1020, a storage device 1030, an input/output (I/O) device 1040, a power supply 1050, and a display device 1060. The display device 1060 may correspond to any one of the display device DD of FIG. 3, the display device DD2 of FIG. 6, the display device DD3 of FIG. 8, and the display device DD4 of FIG. 10. In addition, the electronic device 1000 may further include a plurality of ports for communicating with a video card, a sound card, a memory card, a universal serial bus (USB) device, other systems, and the like.

In an embodiment, as illustrated in FIG. 13, the electronic device 1000 may be implemented as a smart phone. However, the electronic device 1000 is not limited thereto. For example, the electronic device 1000 may be implemented as a smart pad, a smart watch, a tablet PC, a car navigation system, a computer monitor, a laptop, a head mounted display (“HMD”) device, and the like.

The processor 1010 may perform various computing functions. The processor 1010 may be a microprocessor, a central processing unit (“CPU”), an application processor (“AP”), and the like. The processor 1010 may be coupled to other components through an address bus, a control bus, a data bus, and the like. In an embodiment, the processor 1010 may be coupled to an extended bus such as a peripheral component interconnection (“PCI”) bus.

The memory device 1020 may store data for operations of the electronic device 1000. For example, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, and the like and/or at least one volatile memory device such as a dynamic random access memory (“DRAM”) device, a static random access memory (“SRAM”) device, a mobile DRAM device, and the like.

The storage device 1030 may include a solid-state drive (“SSD”) device, a hard disk drive (“HDD”) device, a CD-ROM device, and the like. The I/O device 1040 may include an input device such as a keyboard, a keypad, a mouse device, a touch-pad, a touch-screen, and the like, and an output device such as a printer, a speaker, and the like. In some embodiments, the I/O device 1040 may include the display device 1060.

The power supply 1050 may provide power for operations of the electronic device 1000. In other words, the power supply 1050 may provide power to the display device 1060 (or, the display panel). The display device 1060 may be connected to other components through buses or other communication links.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. A display device comprising:
a substrate including a display area and a bending area positioned on one side of the display area, a lower surface of the substrate defining a plurality of openings;
a shielding layer disposed along the lower surface of the substrate and continuously extending within the plurality of openings; and
a first organic layer disposed under the shielding layer and flattening a lower surface of the shielding layer.

2. The display device of claim 1, wherein the shielding layer defines a plurality of grooves overlapping the plurality of openings, respectively, and
the first organic layer covers the plurality of grooves.

3. The display device of claim 2, wherein the first organic layer fills the plurality of grooves.

4. The display device of claim 2, wherein each of the plurality of grooves includes a pore.

5. The display device of claim 1, wherein a first modulus of elasticity of the first organic layer is smaller than a second modulus of elasticity of the substrate.

6. The display device of claim 1, wherein the shielding layer includes at least one of copper, graphite, and carbon nanotube.

7. The display device of claim 1, wherein the first organic layer includes an organic material including a light blocking material with a black color.

8. The display device of claim 1, wherein the plurality of openings overlap the display area and are spaced apart from the bending area in a plan view.

9. The display device of claim 1, wherein each of the shielding layer and the first organic layer overlaps the display area and is spaced apart from the bending area in a plan view.

10. The display device of claim 1, wherein each of the plurality of openings penetrates the substrate in a thickness direction of the substrate.

11. The display device of claim 1, wherein the substrate further includes a pad area spaced apart from the display area in a plan view with the bending area between the pad area and the display area.

12. The display device of claim 11, further comprising:
a second organic layer disposed on the lower surface of the substrate and overlapping the pad area in the plan view.

13. The display device of claim 12, wherein the second organic layer and the first organic layer include a same material.

14. The display device of claim 12, wherein the second organic layer includes a different material from the first organic layer, and
a third modulus of elasticity of the second organic layer is greater than a first modulus of elasticity of the first organic layer.

15. A display device comprising:
a substrate including a display area and a bending area positioned on one side of the display area, a lower surface of the substrate defining a plurality of openings;
a first organic layer disposed under the substrate and covering the plurality of openings; and
a shielding layer disposed under the first organic layer and covering a lower surface of the first organic layer.

16. The display device of claim 15, wherein the first organic layer fills the plurality of openings.

17. The display device of claim 15, wherein the first organic layer is disposed outside the plurality of openings, and
each of the plurality of openings includes a pore.

18. The display device of claim 15, wherein the shielding layer has a flat upper surface.

19. The display device of claim 15, wherein a first modulus of elasticity of the first organic layer is smaller than a second modulus of elasticity of the substrate.

20. The display device of claim 15, wherein the shielding layer includes at least one of copper, graphite, and carbon nanotube.

21. The display device of claim 15, wherein the first organic layer includes an organic material including a light blocking material with a black color.

22. The display device of claim 15, wherein the plurality of openings overlap the display area and are spaced apart from the bending area in a plan view.

23. The display device of claim 15, wherein each of the shielding layer and the first organic layer overlaps the display area and is spaced apart from the bending area in a plan view.

24. The display device of claim 15, wherein each of the plurality of openings penetrates the substrate in a thickness direction of the substrate.

25. The display device of claim 15, wherein the substrate further includes a pad area spaced apart from the display area in a plan view with the bending area between the pad area and the display area.

26. The display device of claim 25, further comprising:
a second organic layer disposed on the lower surface of the substrate and overlapping the pad area in the plan view.

27. The display device of claim 26, wherein the second organic layer and the first organic layer include a same material.

28. The display device of claim 26, wherein the second organic layer includes a different material from the first organic layer, and
a third modulus of elasticity of the second organic layer is greater than a first modulus of elasticity of the first organic layer.

29. An electronic device comprising:
a display panel including a display area and a bending area positioned on one side of the display area, a lower surface of the display panel defining a plurality of openings;
a shielding layer disposed along the lower surface of the display panel and continuously extending within the plurality of openings;
a first organic layer disposed under the shielding layer and flattening a lower surface of the shielding layer; and
a power supply configured to provide power to the display panel.

30. An electronic device comprising:
a display panel including a display area and a bending area positioned on one side of the display area, a lower surface of the display panel defining a plurality of openings;
a first organic layer disposed under the display panel and covering the plurality of openings;
a shielding layer disposed under the first organic layer and covering a lower surface of the first organic layer; and
a power supply configured to provide power to the display panel.
